(19) United States
(12) Patent Application Publication
(10) Pub. No.: US 2019/0273205 A1
(43) Pub. Date: Sep. 5, 2019

(54) ReRAM DEVICE RESISTIVITY CONTROL BY OXIDIZED ELECTRODE

(71) Applicant: INTERNATIONAL BUSINESS MACHINES CORPORATION, Armonk, NY (US)

(72) Inventors: Takashi Ando, Tuckahoe, NY (US); Eduard A. Cartier, New York, NY (US); Seyoung Kim, Weschester, NY (US); John Bruley, Poughkeepsie, NY (US)

(21) Appl. No.: 15/911,821

(22) Filed: Mar. 5, 2018

(51) Int. Cl. H01L 45/00

(52) U.S. Cl. CPC H01L 45/1253; H01L 45/1608; H01L 45/08

(57) ABSTRACT

A method is presented for increasing resistance of a resistive random access memory (ReRAM) device. The method includes forming a first electrode, forming an insulating layer over the first electrode, and forming a second electrode over the insulating layer, the second electrode constructed by depositing a stoichiometric oxygen barrier layer and depositing an oxidized conducting layer directly over the stoichiometric oxygen barrier layer to create a high-resistance conductive path between the first and second electrodes of the ReRAM device.

### BACKGROUND

### Technical Field

The present invention relates generally to semiconductor devices, and more specifically, to controlling a resistance of resistive random access memory (ReRAM) devices by employing an oxidized electrode.

### Description of the Related Art

Memories have been widely used in various electronic products. Due to the increasing need of data storage, the demands of capacities and performances of the memories become higher and higher. Among various memory elements, resistive random access memories (ReRAMs) have a low operating voltage, a high read/write speed, and high miniaturization of element size and, thus, can replace conventional flash memories and dynamic random access memories (DRAMs) as the main stream of memory elements of the next generation.

### SUMMARY

In accordance with an embodiment, a method is provided for increasing resistance of a resistive random access memory (ReRAM) device. The method includes forming a first electrode, forming an insulating layer over the first electrode, and forming a second electrode over the insulating layer, the second electrode constructed by depositing a stoichiometric oxygen barrier layer and depositing an oxidized conducting layer directly over the stoichiometric oxygen barrier layer to create a high-resistance conductive path between the first and second electrodes of the ReRAM device.

In accordance with another embodiment, a method is provided for increasing resistance of a resistive random access memory (ReRAM) device. The method includes forming a first electrode, forming an insulating layer over the first electrode, and forming a partially oxidized second electrode over the insulating layer that enables formation of a high-resistance conductive path between the first electrode and the partially oxidized second electrode of the ReRAM device.

In accordance with yet another embodiment, a semiconductor structure incorporated within a crossbar array is provided. The semiconductor structure includes a first electrode, an insulating layer formed over the first electrode, and a second electrode formed over the insulating layer, the second electrode including a stoichiometric oxygen barrier layer and an oxidized conducting layer formed directly over the stoichiometric oxygen barrier layer to create a high-resistance conductive path between the first and second electrodes.

It should be noted that the exemplary embodiments are described with reference to different subject-matters. In particular, some embodiments are described with reference to method type claims whereas other embodiments have been described with reference to apparatus type claims. However, a person skilled in the art will gather from the above and the following description that, unless otherwise notified, in addition to any combination of features belonging to one type of subject-matter, also any combination between features relating to different subject-matters, in particular, between features of the method type claims, and features of the apparatus type claims, is considered as to be described within this document.

These and other features and advantages will become apparent from the following detailed description of illustrative embodiments thereof, which is to be read in connection with the accompanying drawings.

### BRIEF DESCRIPTION OF THE SEVERAL VIEWS OF THE DRAWINGS

The invention will provide details in the following description of preferred embodiments with reference to the following figures wherein:

FIG. 1 is a cross-sectional view of a semiconductor structure including a bottom electrode, an insulator, and a portion of a top electrode formed over a semiconductor substrate, in accordance with an embodiment of the present invention;

FIG. 2 is a cross-sectional view of the semiconductor structure of FIG. 1 where the portion of the top electrode is oxidized to form a titanium oxy-nitride layer, in accordance with an embodiment of the present invention;

FIG. 3 is a cross-sectional view of the semiconductor structure of FIG. 2 where a low resistivity metal layer is deposited to complete the top electrode and form the metal-insulator-metal (MIM) stack, in accordance with an embodiment of the present invention;

FIG. 4 is a cross-sectional view of the semiconductor structure of FIG. 3 where the metal-insulator-metal (MIM) stack is patterned and etched, in accordance with an embodiment of the present invention;

FIG. 5 is a block/flow diagram illustrating a method for increasing device resistance by partially oxidizing the top electrode of a MIM stack, in accordance with an embodiment of the present invention;

FIG. 6 is a basic cell structure for a one transistor-one resistor (1T1R) RRAM, in accordance with an embodiment of the present invention;

FIG. 7 is an exemplary 3D RRAM crossbar array incorporating the RRAM device of FIG. 3, in accordance with an embodiment of the present invention;

FIG. 8 is an exemplary diagram illustrating prospects of the RRAM device of FIG. 3, in accordance with an embodiment of the present invention;

FIG. 9 is a conventional current versus voltage graph illustrating device characteristics of a ReRAM device having a conventional MIM stack; and

FIG. 10 is a current versus voltage graph illustrating device characteristics of the ReRAM device having the MIM stack structure of FIG. 3, in accordance with an embodiment of the present invention.

Throughout the drawings, same or similar reference numerals represent the same or similar elements.

### DETAILED DESCRIPTION

Embodiments in accordance with the present invention provide methods and devices for implementing a metal-insulator-metal (MIM) device employing a partially oxidized top electrode. MIM devices can be employed in, e.g., the fabrication of integrated circuits. A MIM device includes a MIM dielectric situated between lower and upper metal plates, which form the top and bottom electrodes of the MIM device. MIM devices are used for various applications, such as dynamic random access memory (DRAM) capacitors and decoupling capacitors, as well as for resistive random access memory (ReRAM) devices.

Embodiments in accordance with the present invention provide methods and devices for implementing ReRAM devices that exhibit a high-resistance path between top and bottom electrodes. A dielectric, which is normally insulating, can be made to conduct through a filament or conduction path formed after application of a sufficiently high voltage. The conduction path can arise from different mechanisms, including vacancy or metal defect migration. Once the filament is formed, it can be reset (broken, resulting in high resistance) or set (re-formed, resulting in lower resistance) by another voltage. Thus, there is a presence of at least one current path in the dielectric.

Embodiments in accordance with the present invention provide methods and devices for increasing resistance of resistive random access memory (ReRAM) devices. A partially oxidized top electrode can be employed to form the ReRAM devices. The partially oxidized electrode can include a stoichiometric oxygen barrier layer, an oxidized metal layer, and a low resistivity metal layer. The partially oxidized top electrode can be formed over an insulating layer, which in turn can be formed over a bottom electrode. The partially oxidized top electrode can create a high-resistance path between the top and bottom electrodes. The high-resistance path or filament can be formed in the insulating layer.

In operation, the stoichiometric oxygen barrier layer protects the filament forming layer during formation of the oxidized metal layer such that oxygen vacancies are maintained within the filament forming layer. Oxygen vacancies are the building blocks for the conducting filament. The oxidized metal layer adds a series resistance, which limits the current during the forming step. This enables formation of at least one narrow filament by avoiding positive feedback reaction due to a high leakage current during the formation. Then, a low resistivity metal layer can optionally be deposited over the oxidized metal layer (after the oxidizing step) to reduce spreading resistance within the ReRAM device or cell.

Examples of semiconductor materials that can be employed in forming such structures include silicon (Si), germanium (Ge), silicon germanium alloys (SiGe), silicon carbide (SiC), silicon germanium carbide (SiGeC), III-V compound semiconductors and/or II-VI compound semiconductors. III-V compound semiconductors are materials that include at least one element from Group III of the Periodic Table of Elements and at least one element from Group V of the Periodic Table of Elements. II-VI compound semiconductors are materials that include at least one element from Group II of the Periodic Table of Elements and at least one element from Group VI of the Periodic Table of Elements.

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this invention.

It is to be understood that the present invention will be described in terms of a given illustrative architecture; however, other architectures, structures, substrate materials and process features and steps/blocks can be varied within the scope of the present invention. It should be noted that certain features cannot be shown in all figures for the sake of clarity. This is not intended to be interpreted as a limitation of any particular embodiment, or illustration, or scope of the claims.

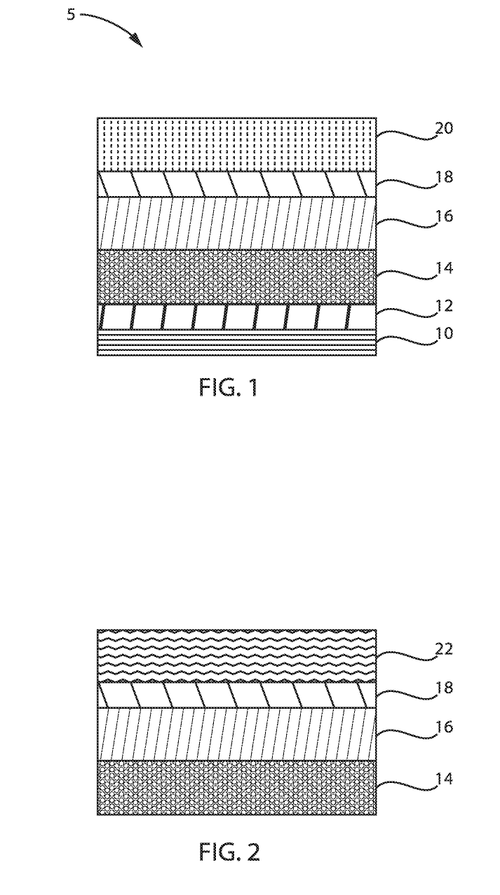

FIG. 1 is a cross-sectional view of a semiconductor structure including a bottom electrode, an insulator, and a portion of a top electrode formed over a semiconductor substrate, in accordance with an embodiment of the present invention.

A semiconductor structure 5 includes a semiconductor substrate 10 with interlayer dielectric (ILD) 12 formed over the semiconductor substrate 10.

In one or more embodiments, the substrate 10 can be a semiconductor or an insulator with an active surface semiconductor layer. The substrate 10 can be crystalline, semi-crystalline, microcrystalline, or amorphous. The substrate 10 can be essentially (i.e., except for contaminants) a single element (e.g., silicon), primarily (i.e., with doping) of a single element, for example, silicon (Si) or germanium (Ge), or the substrate 10 can include a compound, for example, GaAs, SiC, or SiGe. The substrate 10 can also have multiple material layers.

In an exemplary embodiment, the ILD 12 can have a composition that is selected from the group consisting of silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C:H).

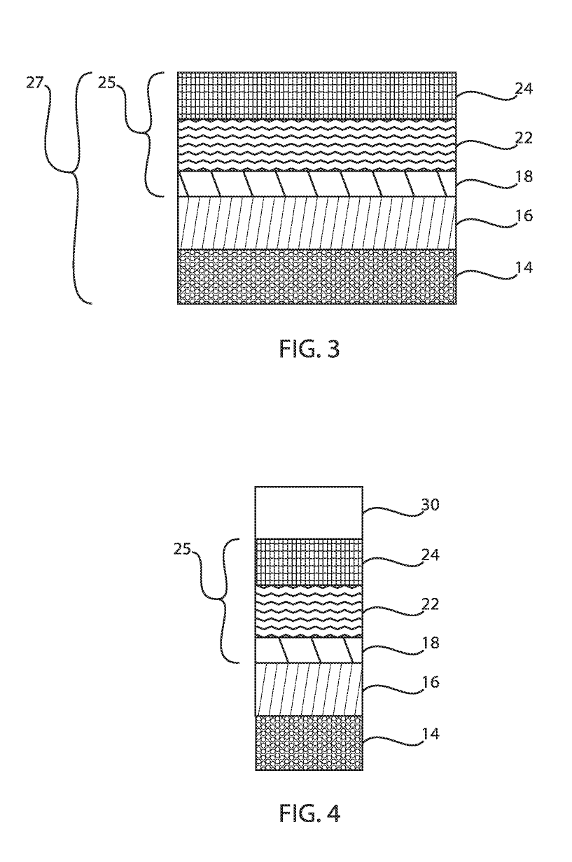

A MIM stack 27 (FIG. 3) can then be formed over the layers 10 and 12.

The MIM stack 27 can be formed as follows.

A bottom electrode 14 can be formed over the ILD 12. The bottom electrode can be, e.g., titanium nitride (TiN), tantalum nitride (TaN) or tungsten (W).

An insulating layer 16 can then formed over the bottom electrode 14. The insulating layer 16 can be, e.g., an oxide. The oxide can be, e.g., hafnium oxide (HfOx), tantalum oxide (TaOx) or titanium oxide (TiOx). The insulating layer 16 can also be referred to as a resistive random access memory (ReRAM) filament forming layer. In other embodiments, the insulating layer 16 can also be referred to as an oxygen deficient metal oxide layer 16 or a transition metal oxide layer 16.

A portion of the top electrode is formed over the insulating layer 16. The top electrode includes, at this point, a first layer 18 and a second layer 20. The first layer 18 can be, e.g., a stoichiometric oxygen barrier layer, such as, e.g., a TiN layer. The second layer 20 can be, e.g., a Ti-rich TiN layer.

FIG. 2 is a cross-sectional view of the semiconductor structure of FIG. 1 where the portion of the top electrode is oxidized to form a titanium oxy-nitride layer, in accordance with an embodiment of the present invention.

In various exemplary embodiments, the top electrode is partially oxidized. Oxidation occurs under low O₂ partial pressure with a temperature of about 350° C. to about 450° C. The O₂ partial pressure is set to less than about 1 Torr. The partial oxidation of the top electrode results in the Ti-rich TiN layer 20 being converted to a titanium oxy-nitride (TiON) layer 22 due to its stronger affinity to oxygen.

FIG. 3 is a cross-sectional view of the semiconductor structure of FIG. 2 where a low resistivity metal layer is deposited to complete the top electrode and form the MIM stack, in accordance with an embodiment of the present invention.

In various exemplary embodiments, a third layer 24 is deposited over the TiON layer 22 to form the top electrode 25. The MIM 27 thus includes a top electrode 25 having three layers, that is layers 18, 22, 24. The third layer 24 can be, e.g., a low resistivity metal layer. The low resistivity metal layer 24 can be, e.g., a tantalum nitride (TaN) layer. In other example embodiments, the low resistivity metal layer 24 can be, e.g., titanium nitride (TiN), tungsten (W), aluminum (Al) or copper (Cu). Therefore, in one example, the top electrode 25 can be formed by three layers, that is, a stoichiometric oxygen barrier layer 18, an oxidized metal layer 22, and a low resistivity metal layer 24.

Moreover, the material for the top metallic electrode 25 and the bottom metallic electrode 14 can be selected from, but is not limited to, platinum (Pt), TiN, titanium carbide (TiC), TaN, tantalum carbide (TaC), cobalt iron boron (CoFeB), W, as well as combinations thereof. Also, the layers of the MIM structure 27 can be formed, for example, by chemical vapor deposition (CVD), physical vapor deposition (PVD), atomic layer deposition (ALD), and/or other techniques known in the art.

In operation, in the OFF state, a ReRAM device has a high electrical resistance. When a voltage is applied, positively charged ions are released from the top electrode and migrate to the bottom electrode where they gain electrons and form atoms again. An electrically conductive filament is created between the top and bottom electrodes. In such case, the ReRAM device usually has a low resistance (ON state) or, stated differently, a low resistance path is created between the top and bottom electrodes. The exemplary embodiments of the present invention, on the other hand, can create a high-resistance path between the top and bottom electrodes by employing an oxidized metal layer to form the top electrode.

In particular, according to the exemplary embodiments of the present invention, the stoichiometric oxygen barrier layer 18 protects the filament forming layer 16 during formation of the oxidized metal layer 22 such that oxygen vacancies are maintained. Oxygen vacancies are the building blocks for the conducting filament. The oxidized metal layer 22 adds a series resistance, which limits the current during the forming step. This enables formation of a narrow filament by avoiding positive feedback reaction due to a high leakage current during the forming. Then, a low resistivity metal layer 24 can optionally be deposited over the oxidized metal layer 22 (after the oxidizing step) to reduce the spreading resistance within the ReRAM cell.

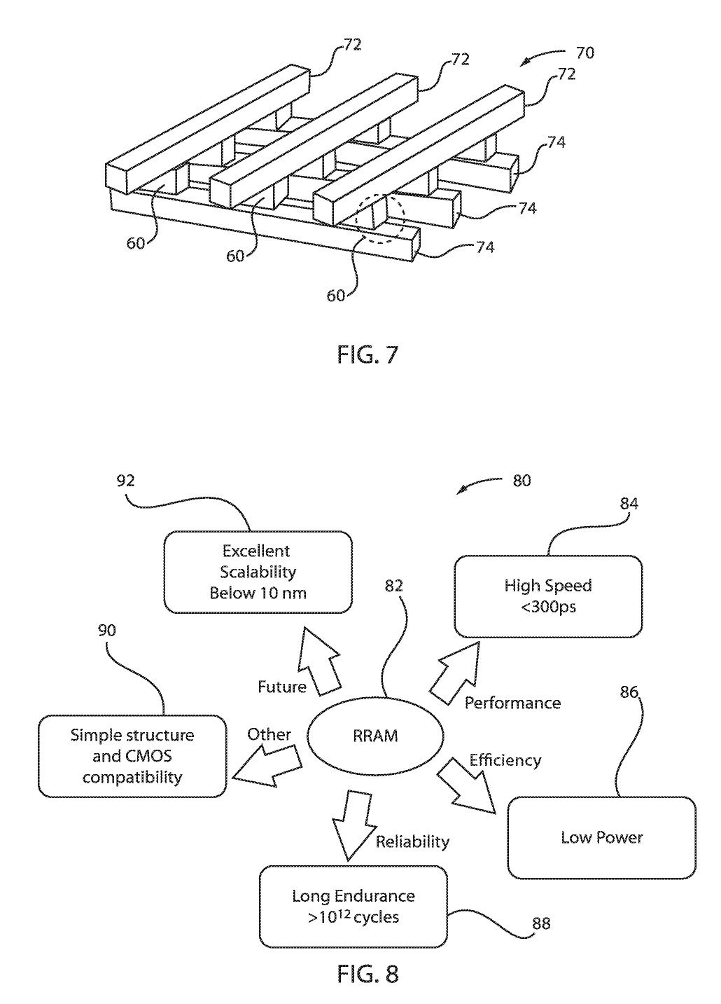

Therefore, a metal-insulator-metal stack structure having a partially oxidized top electrode can be employed to significantly increase the ReRAM device resistance to a point where such ReRAMs can be utilized in crossbar arrays (FIG. 7). One example MIM stack structure can be, e.g., a TiN/HfOx/TiN/TiON stack structure. Of course, one skilled in the art can contemplate replacing such materials with other materials or material combinations as suggested throughout the present specification. In certain non-limiting examples, the metals can be, e.g., TaN, W, Al, and Cu, and the insulator can be, e.g., TaOx and TiOx. The crossbar arrays can then be employed in neuromorphic computing applications. In neuromorphic computing applications, ReRAMs can be used as a connection (synapse) between a pre-neuron and a post-neuron. Multiple pre-neurons and post-neurons can be connected through a crossbar array format. In order to construct large-scale crossbar arrays, each cross point needs to have a high resistance (or low leakage current). The ReRAM devices of the exemplary embodiments of the present invention having the TiN/HfOx/TiN/TiON stack structure of the top electrode can be employed to significantly increase the ReRAM device resistance (high-resistance paths) to the point where they can be implemented in large crossbar arrays.

FIG. 4 is a cross-sectional view of the semiconductor structure of FIG. 3 where the MIM stack is patterned and etched, in accordance with an embodiment of the present invention.

In various exemplary embodiments, the ReRAM cell can be patterned by lithography and reactive ion etching (RIE) processes. For example, a mask 30 can be deposited over the MIM 27 and the top electrode, bottom electrode, and insulating layer can be etched to smaller dimensions.

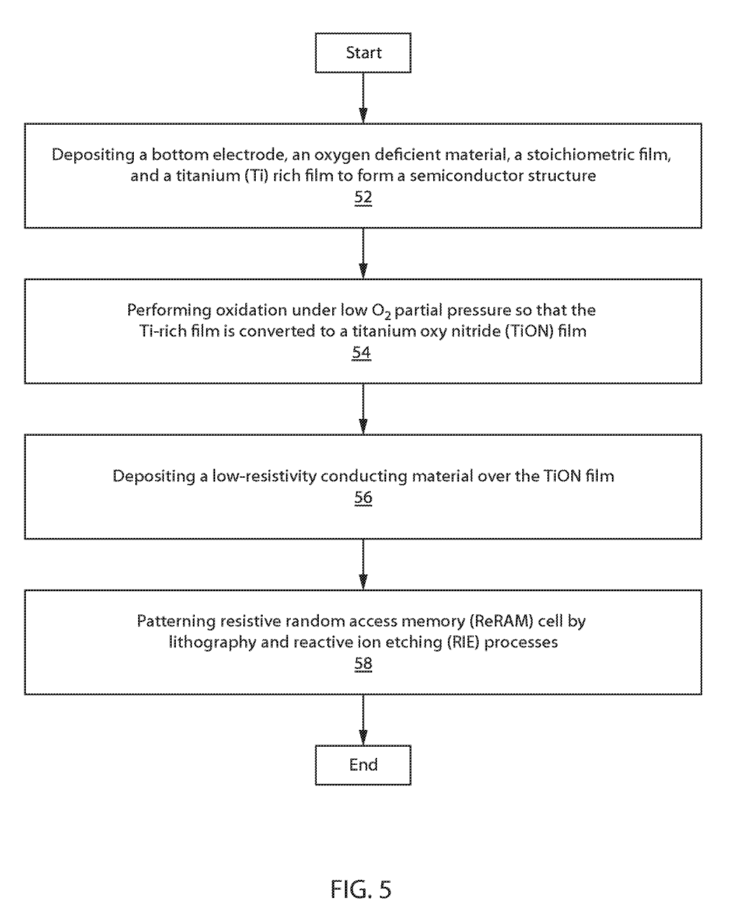

FIG. 5 is a block/flow diagram illustrating a method for increasing device resistance by partially oxidizing the top electrode of a MIM stack, in accordance with an embodiment of the present invention.

At block 52, a bottom electrode, an oxygen deficient material, a stoichiometric film, and a titanium (Ti) rich film are deposited to form a semiconductor structure. The bottom electrode can be, e.g., a TiN layer. The oxygen deficient material can be, e.g., hafnium oxide (HfOx).

At block 54, oxidation is performed under low O₂ partial pressure so that the Ti-rich film is converted to a titanium oxy nitride (TiON) film. Oxidation occurs under low O₂ partial pressure with a temperature of about 350° C. to about 450° C. The O₂ partial pressure is set to less than 1 Torr. The partial oxidation of the top electrode results in the Ti-rich TiN layer being converted to a titanium oxy-nitride (TiON) layer due to its stronger affinity to oxygen.

At block 56, a low-resistivity conducting material is optionally deposited over the TiON film. The low-resistivity conducting material can be, e.g., TaN.

At block 58, the resistive random access memory (ReRAM) cell is patterned by lithography and reactive ion etching (RIE) processes. For example, a mask can be deposited over the MIM and the top electrode, bottom electrode, and insulating layer can be etched to smaller dimensions.

By applying an external voltage across the ReRAM cell, the ReRAM cell can be switched between a high resistance state (HRS or OFF-state) and a low resistance state (LRS or ON-state), which are used to represent the logical “0” and “1”, respectively. According to the polarity of the programming voltage, ReRAM cells can be classified into unipolar ReRAM and bipolar ReRAM. The resistance switching of a unipolar ReRAM only depends on the magnitude of programming voltage, whereas in bipolar ReRAM, HRS-to-LRS switching (SET operation) and LRS-to-HRS switching (RESET operation) need programming voltages with opposite polarities. Compared to unipolar ReRAM, bipolar ReRAM is more attractive because of its good cell characteristics, better switching uniformity, and operating margin.

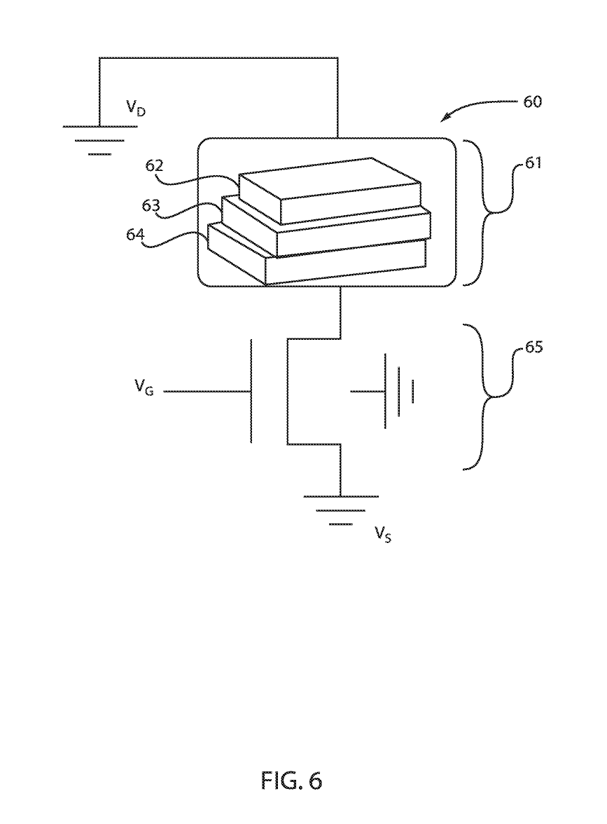

FIG. 6 is a basic cell structure for a 1T1R-RRAM, in accordance with an embodiment of the present invention.

In various example embodiments, the cell structure 60 includes the resistive switching memory element 61 and a transistor 65. The resistive switching memory element 61 can include an insulating layer 63 sandwiched between a first metal layer 62 and a second metal layer 64. The transistor 65 includes a source, drain, and gate. In one example, the resistive switching memory element 61 is placed in series with the drain.

FIG. 7 is an exemplary RRAM crossbar array 70 incorporating the RRAM device of FIG. 3, in accordance with an embodiment of the present invention.

In various example embodiments, the RRAM stack 60 represents a memory cell incorporated between a plurality of bit lines 72 and a plurality of word lines 74. Thus, the array 70 is obtained by perpendicular conductive wordlines (rows) 74 and bitlines (columns) 72, where a cell structure 60 with resistive memory element exists at the intersection between each row and column. The cell structure 60 with resistive memory element can be accessed for read and write by biasing the corresponding wordline 74 and bitline 72.

Therefore, one possible ReRAM array organization is based on the one-transistor-one-resistor (1T1R) ReRAM cell structure. In this structure, a metal oxide semiconductor field effect transistor (MOSFET) transistor can be integrated with the ReRAM cell as the access device. With this design, it is possible to accurately control the current to the activated cells through their dedicated access transistors. On the flip side, the size of MOSFET should be large enough to satisfy the current needs of the SET and RESET operations. This ultimately increases the cell area and cost. One solution to reduce the cost is to organize an ReRAM array in an area-efficient crossbar structure 70, which eliminates the access transistor, as shown in FIG. 7.

FIG. 8 is an exemplary diagram 80 illustrating the prospects of the RRAM device of FIG. 3, in accordance with an embodiment of the present invention.

In various example embodiments, the RRAM-based device 82 provides for high speed processing 84, low power consumption 86, long endurance 88, simple structure and CMOS compatibility 90, and scalability 92. These factors help RRAM-based devices 82 achieve better performance, higher efficiency, and more reliability. Such RRAM based device is described with reference to FIG. 1-4.

Resistive random access memory (RRAM) is considered a promising technology for electronic synapse devices or memristor devices for neuromorphic computing, as well as high-density and high-speed non-volatile memory applications. In neuromorphic computing applications, a resistive memory device can be used as a connection (synapse) between a pre-neuron and a post-neuron, representing connection weight in the form of device resistance. Multiple pre-neurons and post-neurons can be connected through a crossbar or crosspoint array of RRAMs, which naturally expresses a fully-connected neural network.

In order to construct a large scale crossbar array, each cross point needs to have a high resistance (or low leakage current). Otherwise, voltage drop across the metal lines becomes an issue. RRAM devices usually have low switching resistance (˜kOhm) due to a filamentary nature. The exemplary embodiments of the present invention alleviate ReRAM issues by creating a MIM stack having a partially oxidized top electrode.

Moreover, emerging memories can be fabricated in the BEOL at relatively low temperatures, which allows for easy integration with complementary metal oxide semiconductor (CMOS) devices and stacking in 3D. For all these reasons, resistive memories are promising not only for nonvolatile memories, but also for computing memories, thus allowing for fast data access and for computing architectures blurring a distinction between memory and computing circuits, such as nonvolatile memristive logic computation or neuromorphic networks.

Among the emerging memory technologies, RRAM or ReRAM is one of the most promising devices given its good cycling endurance, high speed, ease of fabrication and good scaling behavior. One of the most significant strengths of RRAM against phase change memory (PCM) and spin-transfer torque memories (STTRAM) is its simple structure, including only an insulating layer inserted between two or more metallic layers. Also, current consumption in RRAM is low because of filamentary conduction, whereas a programming current in PCM and STTRAM is proportional to a device area.

Given this strong potential, large scale RRAM or ReRAM devices are presented herein using a crossbar architecture. ReRAM has also been demonstrated with a relatively small scale, aimed at embedded memory applications in the automotive industry, smart cards, and smart sensors for Internet of Things (IoT) markets. Embedded RRAM provides advantages over flash memory, such as lower energy consumption and higher speed. On the other hand, crossbar RRAM offers a higher density compared to DRAM and a higher speed compared to flash memory, in addition to nonvolatile behavior and 3D integration. These are ideal properties for storage class memory (SCM) applications, filling a gap between DRAM (high performance, low density) and flash memory (high density, slow operation). The exemplary embodiments of the present invention can achieve such results by employing a partially oxidized top electrode to form the ReRAM device.

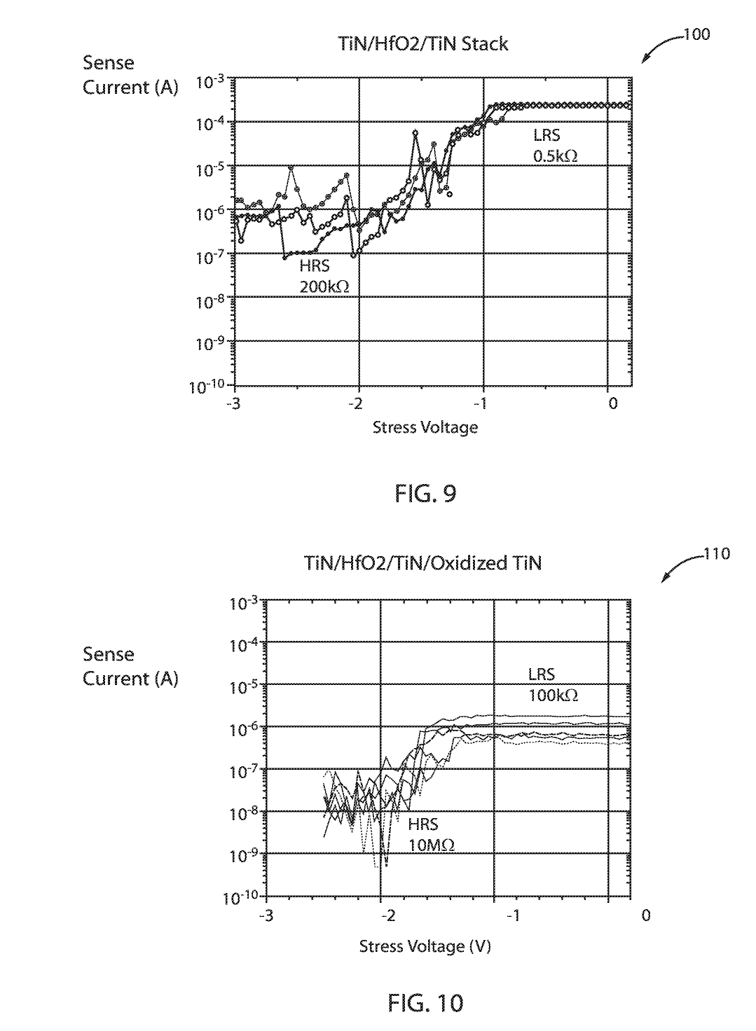

FIG. 9 is a conventional current versus voltage graph 100 illustrating device characteristics of a ReRAM device having a conventional MIM stack whereas FIG. 10 is a current versus voltage graph 110 illustrating device characteristics of the ReRAM device having the MIM stack structure of FIG. 3 with the partially oxidized top electrode, in accordance with an embodiment of the present invention.

As shown in FIG. 10, graph 110 illustrates a 50-200 times increase of device resistance being obtained by using the ReRAM stack of FIG. 3. For example, the low resistance state (LRS) is approximately 100 kΩ and the high resistance state (HRS) is approximately 10 MΩ. In particular, switching a cell from HRS to LRS is a SET operation, and the reverse process is a RESET operation. To SET the cell, a positive voltage that can generate sufficient write current is necessary. To RESET the cell, a negative voltage with proper magnitude is necessary. To read the state of a cell, a read voltage is applied which should be small enough in order not to flip the cell unintentionally. FIG. 10 illustrates that the LRS can be RESET to a large resistance for the ReRAM of the exemplary embodiments of the present invention compared to conventional ReRAM devices.

Regarding FIGS. 1-4, deposition is any process that grows, coats, or otherwise transfers a material onto the wafer. Available technologies include, but are not limited to, thermal oxidation, physical vapor deposition (PVD), chemical vapor deposition (CVD), electrochemical deposition (ECD), molecular beam epitaxy (MBE) and more recently, atomic layer deposition (ALD) among others. As used herein, “depositing” can include any now known or later developed techniques appropriate for the material to be deposited including but not limited to, for example: chemical vapor deposition (CVD), low-pressure CVD (LPCVD), plasma-enhanced CVD (PECVD), semi-atmosphere CVD (SACVD) and high density plasma CVD (HDPCVD), rapid thermal CVD (RTCVD), ultra-high vacuum CVD (UHVCVD), limited reaction processing CVD (LRPCVD), metal-organic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation.

“Removal” is any process that removes material from the wafer: examples include etch processes (either wet or dry), and chemical-mechanical planarization (CMP), etc.

“Patterning” is the shaping or altering of deposited materials, and is generally referred to as lithography.

The term “processing” as used herein includes deposition of material or photoresist, patterning, exposure, development, etching, cleaning, stripping, implanting, doping, stressing, layering, and/or removal of the material or photoresist as required in forming a described structure.

It is to be understood that the present invention will be described in terms of a given illustrative architecture; however, other architectures, structures, substrate materials and process features and steps/blocks can be varied within the scope of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical mechanisms (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which include multiple copies of the chip design in question that are to be formed on a wafer. The photolithographic masks are utilized to define areas of the wafer to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ, where x is less than or equal to 1, etc. In addition, other elements can be included in the compound and still function in accordance with the present embodiments. The compounds with additional elements will be referred to herein as alloys. Reference in the specification to “one embodiment” or “an embodiment” of the present invention, as well as other variations thereof, means that a particular feature, structure, characteristic, and so forth described in connection with the embodiment is included in at least one embodiment of the present invention. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of a method for employing a partially oxidized top electrode in a ReRAM device to achieve at least one high-resistance conductive path (which are intended to be illustrative and not limiting), it is noted that modifications and variations can be made by persons skilled in the art in light of the above teachings. It is therefore to be understood that changes may be made in the particular embodiments described which are within the scope of the invention as outlined by the appended claims. Having thus described aspects of the invention, with the details and particularity required by the patent laws, what is claimed and desired protected by Letters Patent is set forth in the appended claims.

1. A method for increasing resistance of a resistive random access memory (ReRAM) device, the method comprising:
forming a first electrode;
forming an insulating layer in direct contact with the first electrode; and
forming a second electrode in direct contact with the insulating layer, the second electrode constructed by:
depositing a stoichiometric oxygen barrier layer;
depositing a planar titanium-rich layer in direct contact with the stoichiometric oxygen barrier layer; and
converting, by oxidation, the planar titanium-rich layer to a planar titanium oxy-nitride layer to create a high-resistance conductive path within the ReRAM device.

2. The method of claim 1, further comprising constructing the first electrode from titanium nitride (TiN).

3. The method of claim 1, further comprising constructing the insulating layer from a transition metal oxide.

4. The method of claim 1, further comprising depositing a low resistivity metal layer over and in direct contact with the planar titanium oxy-nitride layer.

5. The method of claim 4, further comprising constructing the low resistivity metal layer from one of TiN, tantalum nitride (TaN), tungsten (W), aluminum (Al) or copper (Cu).

6. The method of claim 1, wherein the stoichiometric oxygen barrier layer protects the insulating layer such that oxygen vacancies are maintained in the insulating layer.

7. The method of claim 1, wherein the oxidation occurs under low O₂ partial pressure.

8. The method of claim 7, wherein the oxidation occurs at a temperature of about 350° C. to about 450° C.

9. A method for increasing resistance of a resistive random access memory (ReRAM) device, the method comprising:
forming a first electrode;
forming an insulating layer in direct contact with the first electrode; and
forming a partially oxidized second electrode in direct contact with the insulating layer that enables formation of a high-resistance conductive path within the ReRAM device, the partially oxidized second electrode formed by converting, by oxidation, a planar titanium-rich layer to a planar titanium oxy-nitride layer.

10. The method of claim 9, wherein the the high-resistance conductive path is formed in the insulating layer.

11. The method of claim 9, further comprising depositing a low resistivity metal layer over the planar titanium oxy-nitride layer.

12. The method of claim 9, wherein a stoichiometric oxygen barrier layer protects the insulating layer such that oxygen vacancies are maintained in the insulating layer.

13. The method of claim 11, wherein the oxidation occurs under low O₂ partial pressure.

14. The method of claim 13, wherein the oxidation occurs at a temperature of about 350° C. to about 450° C.

15. The method of claim 9, further comprising constructing the first electrode from titanium nitride (TiN).

16. The method of claim 9, further comprising constructing the insulating layer from a transition metal oxide.

17. A metal-insulator-metal structure incorporated within a crossbar array, the metal-insulator-metal structure comprising:
a first electrode;
an insulating layer formed over the first electrode; and
a second electrode formed over the insulating layer, the second electrode including:
a stoichiometric oxygen barrier layer; and
an oxidized conducting layer formed directly over the stoichiometric oxygen barrier layer to create a high-resistance conductive path between the first and second electrodes.

18. The metal-insulator-metal structure of claim 17, wherein the metal-insulator-metal structure is a resistive random access memory (ReRAM) device.

19. The metal-insulator-metal structure of claim 17, wherein the stoichiometric oxygen barrier layer protects the insulating layer such that oxygen vacancies are maintained in the insulating layer.

20. The metal-insulator-metal structure of claim 17, wherein a low resistivity metal layer is formed over the oxidized conducting layer.
